(19) United States
(12) Patent Application Publication
(10) Pub. No.: US 2014/0096811 A1
(43) Pub. Date: Apr. 10, 2014

(54) Modular Photovoltaic Generator

(71) Applicant: ILAND GREEN TECHNOLOGIES SA, Neuchatel (CH)

(72) Inventor: Daniele Oppizzi, Neuchatel (CH)

(21) Appl. No.: 13/828,163

(22) Filed: Mar. 14, 2013

(30) Foreign Application Priority Data
Oct. 4, 2012 (CH) 1862/12

(51) Int. Cl. H01L 31/045; H01L 31/05

(52) U.S. Cl. CPC H01L 31/045; H01L 31/05
USPC 136/245

(57) ABSTRACT

Photovoltaic generator comprising several flexible photovoltaic panels (1) assembled to one another. The photovoltaic panels are provided with hook-and-loop (Velcro) connectors that are electrically conductive and that secure both the electric connection between adjacent photovoltaic panels and their mechanical attachment.

The present application claims priority of Swiss patent application CH2012/1862, filed on Oct. 04, 2012, the contents of which is hereby enclosed by reference.

### TECHNICAL FIELD

The present invention relates to a flexible photovoltaic generator.

### STATE OF THE ART

Photovoltaic panels whose active surface is made of a thin-film silicon layer are known in the prior art. When this silicon surface is mounted onto a flexible substrate, the entire panel is flexible. Such panels have been used for example to make photovoltaic generators that can be rolled up, photovoltaic clothes or bags, photovoltaic blinds etc.

The surface of these panels is generally fixed in advance and the users cannot modify it according to their needs. The connection of several photovoltaic generators serially or in parallel is sometimes possible but most often than not requires numerous operations to connect mechanically and electrically the photovoltaic panels to one another. Furthermore, the possible combinations are generally limited; the nominal voltage and the nominal current required by the powered electricity-consuming devices constrain the number of photovoltaic panels that must be connected serially and in parallel.

Furthermore, the surface obtained by connecting several generators to one another is most often rectangular. Such a surface is difficult to hide, notably in nature. However, for many applications, notably for hunting, camping, military applications etc., what is wanted are non rectangular photovoltaic generators that are easier to hide and that have shapes that can vary according to the needs of the user to adapt to the most varied backing materials.

### BRIEF SUMMARY OF THE INVENTION

One aim of the present invention is thus to propose a photovoltaic generator with which the problems of the prior art can be solved.

According to the invention, this aim is achieved notably by means of a photovoltaic generator comprising several flexible photovoltaic panels connected to one another and provided with fast connectors that secure both the electric connection between adjacent panels and their mechanical attachment.

The use of fast connectors, for example hook-and-loop (Velcro) fasteners or other types of connectors, makes it possible to attach the different photovoltaic panels of the generator very easily to one another. Advantageously, these fast connectors also enable the electric connections between the panels to be established, so that the assembly is particularly easy. These connectors can for example be placed at the periphery of the panels.

This solution is particularly adapted to small-size photovoltaic panels, for example generators formed by assembling photovoltaic panels whose individual area is less than 20×20 cm², preferably lower than 15×15 cm². Thanks to the ease of assembly, the considerable number of panels necessary for covering a large surface requires only a small amount of additional work. This small area of each panel however allows surfaces to be generated that have very modular dimensions and shapes to adapt to the most varied needs.

The generator can thus comprise interchangeable photovoltaic panels that can be assembled freely to one another in order to vary the shape and surface area obtained. In one embodiment, each photovoltaic panel is of an essentially rectangular shape, for example essentially square. The different panels can then be assembled so as to constitute several rows and several columns. The number of panels per row and the number of panels per column can be different. It is also possible to let holes survive in the middle of the thus formed panel matrix, which makes it even easier to camouflage. It is even possible to obtain a total surface of photovoltaic panels that is not rectangular. It is even possible to modify the shape or the area of this surface at any time, even during operation of the generator.

Each panel can comprise a flexible photovoltaic active surface mounted onto a textile support as well as hook-and-loop (Velcro) connectors on at least two opposite edges. At least one panel can be rectangular, for example square, and comprise a first fast connector, for example but not exclusively a hook-and-loop (Velcro) connector, extending on a first side and on the two adjacent half-sides, as well as a second fast connector extending on at least one portion of the side opposite the first side. The photovoltaic panels can comprise fast connectors on the topside and on the underside in order to assemble while overlapping their edges.

The panel can comprise a hook-and-loop (Velcro) surface and/or buttons or other types of connectors under or around the textile support in order to fasten it in a removable fashion onto an item of clothing, a tent or another support.

The generator advantageously comprises an electronic voltage conversion circuit connected electrically to the panels and arranged so that even if the input voltage depends on the number of photovoltaic panels connected, on the manner in which they are assembled serially and/or in parallel and on the level of sunlight, the output voltage varies less. Thus, the voltage supplied by the generator depends little on the array of photovoltaic panels assembled by the user. A battery can be connected at the exit of the electronic circuit to accumulate the energy produced and subsequently redeliver it. The electronic circuit and the battery can constitute a module that can be placed in a pocket or in the lining of a garment or of a tent onto which the panels are affixed.

### BRIEF DESCRIPTION OF THE FIGURES

Examples of embodiments of the invention are given in the description illustrated by the attached figures in which:

FIG. 1 is a view from above of a photovoltaic panel according to the invention.

FIG. 2 is a view from above and in perspective of a photovoltaic generator according to the invention.

FIG. 3 is a view from above of another array of panels in a photovoltaic generator according to the invention.

### EXAMPLE(S) OF EMBODIMENTS OF THE INVENTION

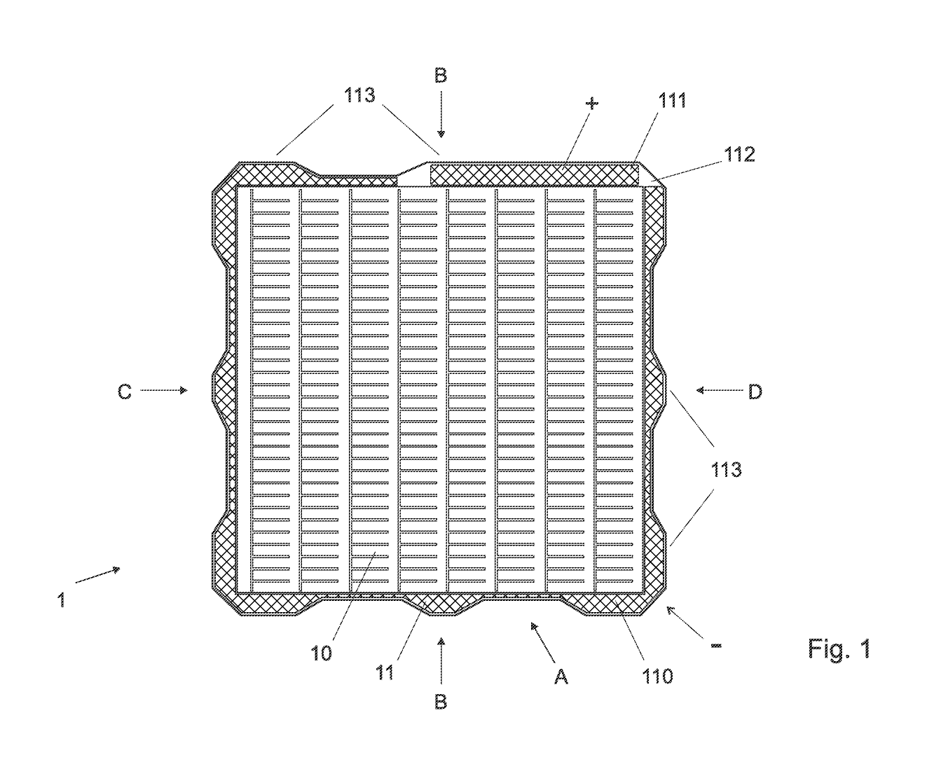

FIG. 1 illustrates a view from above of a flexible photovoltaic panel 1 according to an embodiment of the invention. The panel comprises an active surface 10 formed of several rows of flexible photovoltaic cells connected serially and/or in parallel. The cells can for example be made by deposition of thin-film amorphous silicon layers onto a flexible substrate. This substrate is fastened by gluing and/or sewing onto a textile support 112 whose edges protrude around the periphery of the active surface 10.

In the example illustrated, the active surface 10 has a square shape and the textile support 112 also has an approximately square shape, if disregarding a certain number of flaps 113 designed to facilitate the fastening and unfastening of the panels to one another. Other shapes of panels can however also be used, included rectangular, hexagonal and other shapes. It is also possible to combine panels of different shapes and/or sizes within a single photovoltaic surface formed of assembled panels.

The topside of the periphery of the textile support 112 is provided with a hook-and-loop (Velcro) element 110 (self-adhesive strip), as example of fast connector, extending on the first side A of the panel, on the two adjacent sides C and D and on about half of the side B opposite the first side A. A second hook-and-loop (Velcro) element as example of fast connector 111 is provided on the second half of the side B. The two elements 110, 111 are advantageously of the same type (for example two fastening elements of the hook type or of the velvet type). The underside of the periphery of the textile support 112 is provided with two hook-and-loop (Velcro) elements placed in identical manner, but of opposite type to those of the top side.

These fast connection elements 110, 111 enable a panel 1 to be mechanically fastened to other identical panels, on any of the four sides A, B, C or D of the panel 1, simply by superimposing the peripheral strips of two panels 1 one on top of the other.

At least some elements 110, 111 as well as the corresponding opposite elements on the lower side of the panel 1 are electrically conductive. One of the fast connectors (for example hook-and-loop (Velcro) element 111 on the top) is connected to the first phase of the active surface 10. Another element (for example the hook-and-loop (Velcro) element corresponding to 110 under the surface of the panel 1) is connected to the other minus phase of the active surface 10.

Other arrangements of the fast connection elements 110, 111 can be conceived in the frame of the invention. For example, it is possible to place a single hook-and-loop (Velcro) element or other type of connector connected to one of the phases on the top of the periphery of the panel and another hook-and-loop (Velcro) element or other type of connector connected to the other phase under the periphery of the underside of the panel. The connection between the first phase of a panel and the second phase on the other panel can be achieved by means of several pairs of connectors. Arrangements of hook-and-loop (Velcro) elements can be achieved that make possible the connection of two adjacent panels either serially or in parallel.

Arrangements of connectors that enable electrical and mechanical connections with panels connected on the sides C and/or D are also conceivable. The connectors are electrical conductors and are arranged to allow an electrical connection serially and/or in parallel of the panels, simply by assembling them to one another by means of the connection elements, preferably without additional cables.

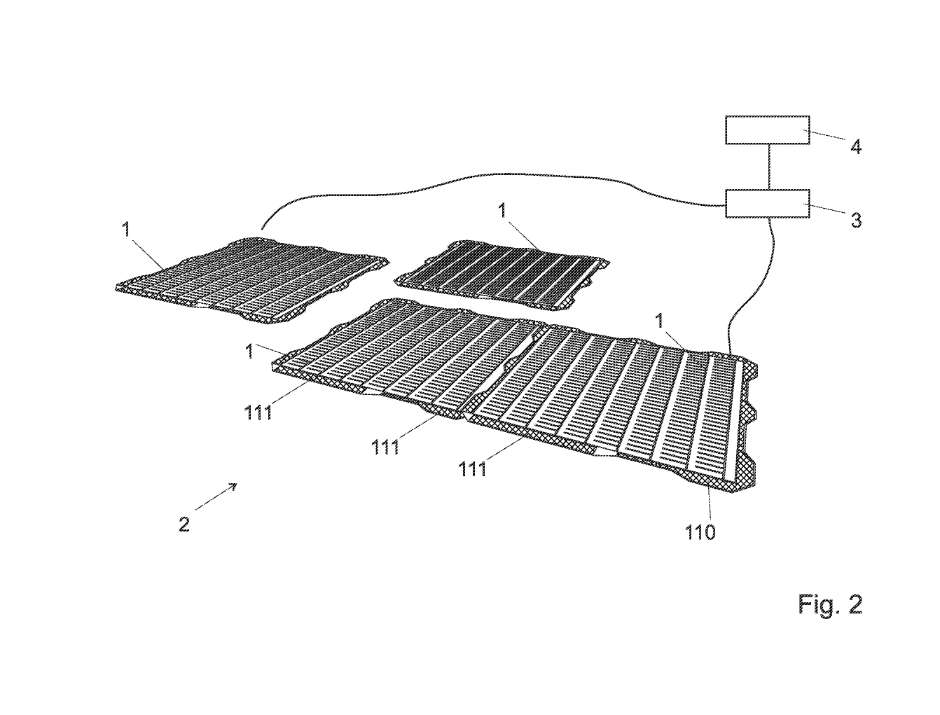

FIG. 2 illustrates a possible arrangement of photovoltaic panels 1 assembled to one another so as to form a complete photovoltaic generator. One panel at the extremity of the chain of panels is connected by an electric wire to a terminal of the electronic circuit 3, whose other terminal is connected by another wire to another panel at the other extremity of the surface. The electric wires can be affixed in a removable fashion by means of hook-and-loop (Velcro) elements or other types of fast connectors onto the hook-and-loop (Velcro) elements 110, 111 of the panels; in one embodiment, at least the end panels are permanently provided with electric wires to connect them electrically to the circuit 3.

The electronic circuit 3 constitutes a direct-direct converter in order to convert the highly variable voltage supplied by the panels at the entry of the circuit with a steady voltage, or at least steadier, that powers a battery 4. The converter 3 can for example have high-voltage semi-conductor elements. The circuit 3 and the battery 4 can for example form a module designed to be integrated in a pocket or in the lining of a garment, of a tent, of a blanket etc.

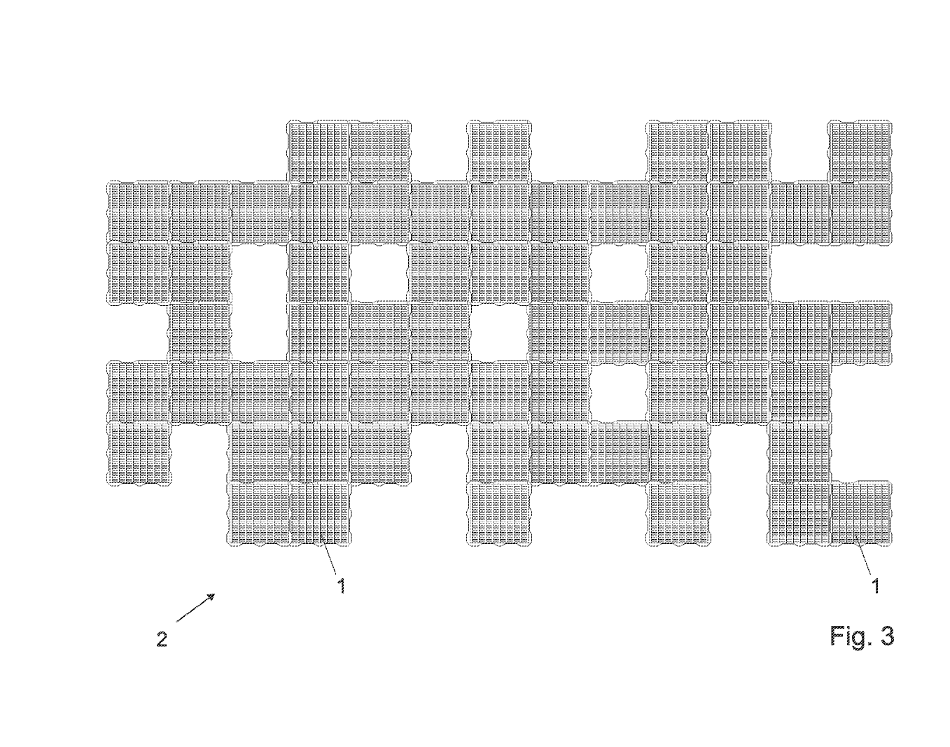

Another array of photovoltaic panels is illustrated in FIG. 3. As can be seen, this array comprises a matrix with panel rows and columns of variable length, including gaps in the middle. The photovoltaic surface thus achieved can be modified and increased or remodeled easily, simply by adding, removing or displacing panels so as to place them in the desired fashion in order to cover at best the desired surface and make the total surface as little visible as possible.

The underside of the panels 1 can be provided with hook-and-loop (Velcro) elements or other types of additional connectors to connect them onto a support, for example a part of a garment, tent, bag, helmet, vehicle etc. Other types of fasteners, for example buttons, can be provided for attaching the photovoltaic surface onto an existing textile. The total surface that can be achieved can vary between a couple of square centimeters to cover the sleeve of a garment, a helmet, a bag etc. up to several square meters to cover a tent, a vehicle, a part of the ground etc.

1. Photovoltaic generator comprising several flexible photovoltaic panels assembled one to another,
wherein said photovoltaic panels are provided with fast connectors that are electrically conductive and that secure both the electric connection between adjacent photovoltaic panels and their mechanical attachment.

2. Photovoltaic generator according to claim 1, wherein said fast connectors can be constituted by hook-and-loop (Velcro) connectors that are electrically conductive.

3. Generator according to claim 1, wherein the surface of each photovoltaic panel is less than 20×20 cm².

4. Generator according to claim 1, wherein said photovoltaic panels are interchangeable.

5. Generator according to claim 1, wherein at least one said photovoltaic panel comprises a flexible active photovoltaic surface mounted on a textile support as well as said hook-and-loop (Velcro) connectors on at least two opposite edges.

6. Generator according to claim 5, comprising a hook-and-loop (Velcro) surface and/or buttons under said textile support in order to fasten it in a removable fashion on an item of clothing.

7. Generator according to claim 2, wherein at least one said photovoltaic panel is rectangular and comprises a first hook-and-loop (Velcro) connector on the topside connected to one of the electric phases of the panel and a second hook-and-loop (Velcro) connector on the underside connected to the other electric phase of the panel.

8. Generator according to claim 7, wherein a hook-and-loop (Velcro) connector extends on a first side and on the two adjacent half-sides of said panel, wherein each panel further comprises a third hook-and-loop (Velcro) connector on the topside extending on at least one portion of the side opposite said first side.

9. Generator according to claim 1, comprising several rows and several columns of said photovoltaic panels, wherein the number of photovoltaic panels per row and the number of photovoltaic panels per column are different.

10. Generator according to claim 9, wherein said rows and columns form a matrix with missing photovoltaic panels.

11. Generator according to claim 1, comprising an electronic circuit connected electrically to said panels in order to stabilize the output voltage.

12. Generator according to claim 11, comprising a battery connected to the exit of said electronic circuit.

13. Generator according to claim 1, wherein said electronic circuit and said battery form a module designed for being placed in an item of clothing and for being connected electrically to two said panels.

14. Flexible photovoltaic panel designed to be assembled with other similar photovoltaic panels to form a generator according to claim 1 and provided with fast connectors that are electrically conductive and that secure both the electric connection with adjacent photovoltaic panels and their mechanical attachment.

15. Photovoltaic panel according to claim 14, wherein the fast connectors are constituted by hook-and-loop (Velcro) connectors that are electrically conductive.

16. Panel according to claim 14, wherein the surface of each panel is less than 100 cm².

17. Panel according to claim 15, comprising a flexible active photovoltaic surface mounted on a textile support as well as said hook-and-loop (Velcro) connectors on at least two opposite sides.

18. Panel according to claim 15, comprising a hook-and-loop (Velcro) surface and/or buttons under said textile substrate in order to fasten it in a removable fashion onto an item of clothing.

19. Panel according to claim 15, being rectangular and having a first hook-and-loop (Velcro) connector extending on a first side and on the two adjacent half-sides and a second hook-and-loop (Velcro) connector extending on at least one portion of the side opposite said first side.
